(19) United States
(12) Patent Application Publication
(10) Pub. No.: US 2013/0015904 A1
(43) Pub. Date: Jan. 17, 2013

(54) POWER GATING CONTROL MODULE, INTEGRATED CIRCUIT DEVICE, SIGNAL PROCESSING SYSTEM, ELECTRONIC DEVICE, AND METHOD THEREFOR

(71) Applicants: Michael Priel, Hertzelia (IL); Anton Rozen, Gedera (IL); Yossi Shoshany, Gan Yavne (IL)

(72) Inventors: Michael Priel, Hertzelia (IL); Anton Rozen, Gedera (IL); Yossi Shoshany, Gan Yavne (IL)

(73) Assignee: FREESCALE SEMICONDUCTOR, INC., Austin, TX (US)

(21) Appl. No.: 13/634,716

(22) PCT Filed: Mar. 22, 2010
(86) PCT No.: PCT/IB2010/051231

§ 371 Date: Sep. 13, 2012

(51) Int. Cl. H03K 17/56

(52) U.S. Cl. 327/419

(57) ABSTRACT

An integrated circuit device comprising at least one signal processing module and a power gating control module arranged to control gating of at least one power supply to at least a part of the at least one signal processing module. The power gating control module is arranged to receive at least one operating parameter; configure at least one power gating setting of the power gating control module based at least partly on the at least one received operating parameter; and apply power gating for at least part of the at least one signal processing module in accordance with the at least one configured power gating setting.

### FIELD OF THE INVENTION

The field of this invention relates to a power gating control module, an integrated circuit device, a signal processing system, an electronic device and a method therefor.

### BACKGROUND OF THE INVENTION

In the field of integrated circuit devices, and in particular in the field of application processor integrated circuit devices, modern integrated circuit devices are, on the one hand, required to provide increasingly high performance whilst on the other hand required to fulfil increasingly stringent power consumption and thermal energy dissipation requirements.

Dynamic voltage and frequency scaling (DVFS) is a known technique that attempts to achieve a balance between good system performance and reduced power consumption of an electronic device. DVFS allows ‘on-the-fly’ voltage and clock frequency adjustment according to the active needs of the system at that time. By reducing the voltage and/or clock frequency for a device, or part of a device, when reduced performance is acceptable, a significant reduction in the dynamic power consumption thereof may be achieved.

However, in order to meet a demand for increasingly high performance, high-leakage process semiconductor devices are needed, in order to achieve the desired high operating frequencies. With the use of such high-leakage process semiconductor devices, power leakage becomes an increasingly significant part of the total power consumption of a device, and in some instances can exceed the dynamic power consumption of the device. Accordingly, whilst DVFS enables the dynamic power consumption of a system to be reduced, it does not address power consumption resulting from high-leakage. Thus, use of DVFS may not be sufficient to enable such high-leakage process semiconductor devices to meet the stringent power consumption requirements for a particular system.

Another known technique for reducing power consumption of an electronic device, whilst maintaining an acceptable level of performance, is State-Retention Power Gating (SRPG). SRPG is a technique that allows the voltage supply to a device to be reduced to zero for a majority of logic gates within a functional block, whilst maintaining a voltage supply to state elements of the functional block, such as registers/buffers. In this manner, power consumption of a functional block within an integrated circuit device may be significantly reduced when the functionality provided by that block is not required, since both dynamic power and static power (the cause of leakage power) are removed from a majority of logic gates. By maintaining a voltage supply to state elements of the functional block, processing by the functional block may be continued quickly when exiting such a powered-down mode.

Nevertheless, waking up a functional block that has been powered down using SRPG still involves a degree of latency, and also involves an energy overhead in charging and discharging capacitances and the like. As such, whilst it is desirable to use SRPG to power down functional blocks within an integrated circuit device as much as possible, in order to maximise the reduction in power consumption, over-use of such a technique may result in a significant degradation in the performance of the system. It may also negate some of the reduction in power consumption due to the energy overhead in charging and discharging capacitances. Accordingly, power saving techniques, such as SRPG, need to be carefully implemented in order to achieve optimal power consumption, whilst avoiding significant degradation in system performance.

### SUMMARY OF THE INVENTION

The present invention provides a an integrated circuit device, a signal processing system, an electronic device, a power gating control module and a method for dynamically controlling gating of at least one power supply to at least a part of a signal processing module, as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIG. 1 illustrates a graph showing an analysis of peak temperature and power leakage for a signal processing system.

FIG. 2 illustrates an example of a signal processing system.

FIG. 3 illustrates examples of power gating cycles.

FIG. 4 illustrates an example of a simplified flowchart of a method for dynamically controlling gating of at least one power supply to at least a part of a signal processing module.

FIG. 5 illustrates an example of a simplified block diagram of part of an electronic device.

### DETAILED DESCRIPTION

The present invention will now be described with reference to a power gating control module arranged to control gating of one or more power supplies to one or more parts of a signal processing system within an integrated circuit device. In particular, examples of the present invention will be described with reference to a power gating control module comprising generally integrated functional elements. However, it will be appreciated that the functional elements for providing the power gating control module are not limited to being provided within in a single functional module.

Furthermore, because the illustrated examples may for the most part, be implemented using electronic components and circuits known to those skilled in the art, details will not be explained in any greater extent than that considered necessary as illustrated below, for the understanding and appreciation of the underlying concept of the present invention and in order not to obfuscate or distract from the teachings of the present invention.

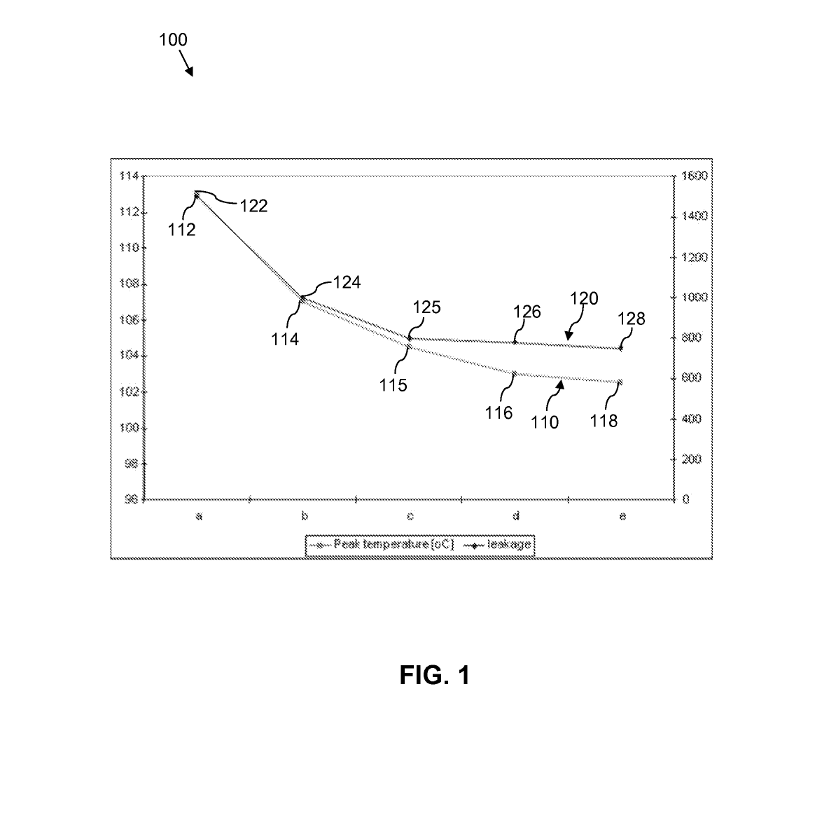

Power gating, also known as power shut off (PSO), is a known technique for arranging functional blocks of a signal processing system to ‘sleep’ by switching off, or ‘gating’, their power supply(ies) using, for example, switching elements such as transistors. In this manner, overall power consumption of a signal processing system may be significantly reduced, albeit potentially at the expense of the overall performance of the system. One implementation of power gating comprises cyclically switching the power supply that is applied to functional blocks on and off at a ‘gating’ frequency rate. Referring now to FIG. 1, there is illustrated a graph 100 comprising plots showing an analysis of peak temperature 110 and power leakage 120 for a signal processing system provided with a power supply that is cyclically switched on and off (gated) for a range of switching frequencies.

At point ‘A’ a generally continuous power supply is provided to a signal processing system, with values for the peak temperature being illustrated at point 112, and for the power leakage being illustrated at point 122.

At point ‘B’ the power supply provided to the signal processing system is cyclically switched on for 2 seconds and then off for 2 seconds, with the corresponding peak temperature and power leakage being illustrated at points 114, 124 respectively.

At point ‘C’ the power supply provided to the signal processing system is cyclically switched on for 1 second and then off for 1 second, with the corresponding peak temperature and power leakage being illustrated at points 115, 125 respectively.

At point ‘D’ the power supply provided to the signal processing system is cyclically switched on for 0.5 seconds and then off for 0.5 seconds, with the corresponding peak temperature and power leakage being illustrated at points 116, 126 respectively.

At point ‘E’ the power supply provided to the signal processing system is cyclically switched on for 0.25 seconds and then off for 0.25 seconds, with the corresponding peak temperature and power leakage being illustrated at points 118, 128 respectively.

As can be seen from the graph 100 illustrated in FIG. 1, as the frequency with which the power supply is ‘pulsed’ increases, both the peak temperature 110 and the power leakage 120 decrease. Accordingly, this would suggest that cyclically powering down functional blocks within a signal processing system at a higher frequency rate, for example as part of a State-Retention Power Gating (SRPG) implementation, is beneficial in terms of reducing the operating temperature of the system, and in reducing the power leakage of the system. However, cyclically powering down functional blocks within a signal processing system at too high a frequency rate can result in significant performance overhead as a result of having to ‘wake-up’ the powered down functional blocks, and also in dynamic energy overhead in charging and discharging capacitors. Thus, power gating for a signal processing system needs to be carefully configured in order to reduce the operating temperature, and (thereby) power leakage, without adversely affecting the performance of the system.

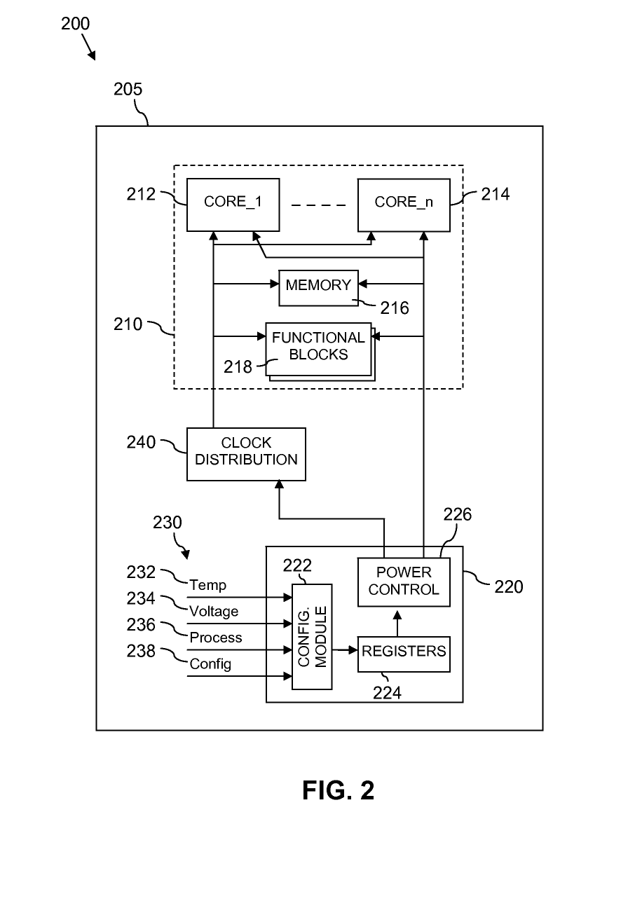

Referring now to FIG. 2, there is illustrated an example of a signal processing system 200. The signal processing system 200 comprises a signal processing module 210, which may comprise a single processing core or, as is the case for the illustrated example, a plurality of processing cores 212, 214, memory element 216 and one or more functional logic blocks 218. Such functional logic blocks 218 may comprise, by way of example only, a video accelerator, graphical accelerator, serial/parallel interface, etc. The signal processing system 200 further comprises power gating control module 220 arranged to control gating of at least one power supply to at least a part of the signal processing module 210, for example to one or more of the processing cores 212, 214, memory element 216 and/or functional logic blocks 218. In particular for the illustrated example, the power gating control module 220 is arranged to receive one or more operating parameters 230, configure at least one power gating setting based at least partly on the one or more received operating parameters 230, and apply power gating for at least part of the signal processing module 210 in accordance with the at least one configured power gating setting.

In this manner, the power gating control module 220 is able to dynamically configure the gating of power supplies for the signal processing system 200 based on the received/or determined operating parameters. As a result, the power gating may be configured according to current operating conditions and/or operating requirements, thereby enabling generally optimal power gating to be achieved for different situations/conditions.

By way of example, an operating parameter received by the power gating control module 220 may comprise an indication of an ambient temperature 232. In this manner, upon receipt of an indication of a low ambient temperature, the power gating control module 220 may be arranged to configure a lower frequency power gating setting for at least part of the signal processing module 210. Conversely, upon receipt of an indication of a high ambient temperature, the power gating control module 220 may be arranged to configure a higher frequency power gating setting for at least part of the signal processing module 210. In this manner, at higher ambient temperatures when the signal processing module 210 is more susceptible to high operating temperatures, and thus more susceptible to power leakage, the power gating control module 220 may configure a higher frequency power gating setting in order to reduce the operating temperature of the signal processing module 210. Conversely, at lower ambient temperatures when the signal processing module 210 is less susceptible to high operating temperatures, the power gating control module 220 may be arranged to configure a lower frequency power gating setting in order to allow for increased performance of the signal processing module 210. Examples of the invention may not be limited to configuring power gating settings based on whether a received temperature indication is high or low. The power gating control module may be arranged to configure power gating settings based at least partly on a plurality of temperature indication threshold values, such that the power gating control module may configure power gating settings according to a range of different settings.

For the illustrated example, the power gating control module 220 is further arranged to receive one or more operating parameters comprising, for example, an indication of a supply voltage 234 for the signal processing module. In this manner, the power gating control module 220 may take into consideration a supply voltage applied to the signal processing module 210 when configuring a power gating setting. For example, upon receipt of an indication of a low supply voltage, for example as may be configured when high performance is not required for the signal processing system, and/or when lower power consumption is a significant requirement, the power gating control module 220 may be arranged to configure a higher frequency power gating setting for at least part of the signal processing module 210. Conversely, upon receipt of an indication of a high supply voltage, for example as may be configured when high performance is required for the signal processing system, and/or when lower power consumption is not a significant requirement, the power gating control module 220 may be arranged to configure a lower frequency power gating setting for at least part of the signal processing module 210. In a similar manner to that for the temperature indications, it will be appreciated that the invention may not be limited to configuring power gating settings based on whether a received supply voltage indication is high or low. It is contemplated that the power gating control module may be arranged to configure power gating settings based at least partly on a plurality of power supply indication threshold values such that the power gating control module may configure power gating settings according to a range of different settings.

For the illustrated example, the power gating control module 220 is still further arranged to receive one or more further operating parameters comprising, for example, an indication of a processing load 236 for the signal processing module. In this manner, the power gating control module 220 may take into consideration a work load of at least a part of the signal processing module 210 when configuring a power gating setting. For example, upon receipt of an indication of a low work load for at least a part of the signal processing module 210, for example one of the processing cores 212, 214 of the signal processing system, the power gating control module 220 may be arranged to configure a higher frequency power gating setting for that part of the signal processing module 210, in order to reduce the power consumption thereof. Conversely, upon receipt of an indication of a high work load for at least a part of the signal processing module 210, the power gating control module 220 may be arranged to configure a lower frequency power gating setting for that part of the signal processing module 210 in order to increase the performance thereof. In some examples, the invention may not be limited to configuring power gating settings based on whether a received work load indication is high or low. For example, the power gating control module may be arranged to configure power gating settings based at least partly on a plurality of work load indication threshold values, such that the power gating control module may configure power gating settings according to a range of different settings.

For the illustrated example, the power gating control module 220 is still further arranged to receive one or more further operating parameters comprising, for example, an indication of one or more configurable settings. For example, a user and/or application program running on the signal processing module 210 may be able to configure, for example by way of configurable registers (not shown), performance and/or power settings. In this manner, the power gating control module 220 may take into consideration such configurable settings when configuring a power gating setting. For example, a user and/or application program may configure such configurable settings to indicate that a system performance is a priority. Accordingly, upon receipt of an indication of such a configured setting, the power gating control module 220 may be arranged to configure a lower frequency power gating setting for at least part of the signal processing module 210, in order to increase the performance thereof. Conversely, a user and/or application program may configure such configurable settings to indicate that low power consumption is a priority. Accordingly, upon receipt of an indication of such a configured setting, the power gating control module 220 may be arranged to configure a higher frequency power gating setting for at least a part of the signal processing module 210 in order to decrease the power consumption thereof. Examples of the invention may not be limited to configuring power gating settings based on whether a received configurable setting indication relates to performance prioritisation or power consumption prioritisation. For example, the power gating control module may be arranged to configure power gating settings based at least partly on a plurality of configurable settings indications such that the power gating control module may configure power gating settings according to a range of different configurable settings.

Thus, the power gating control module 220 may be arranged to receive one or more operating parameters, for example corresponding to:
(i) one or more environmental conditions such as temperature;
(ii) one or more operating conditions such as voltage supply levels and/or work load; and
(iii) one or more configurable conditions,

and to configure power gating settings in accordance with the received operating parameters. The power gating control module 220 may be arranged to configure power gating settings ranging from, say, continuous power supply (i.e. no gating) up to any suitable frequency of power gating, such as by way of example cyclically gating the power supply to a part of the signal processing system with a cyclic period in the order of, say, milliseconds or microseconds.

For the illustrated example, the power gating module 220 comprises a configuration module 222 arranged to receive the one or more operating parameters 230, to determine a power gating configuration based at least partly on the received operating parameters 230, and to configure power gating settings based on the determined power gating configuration. For example, in a simple implementation the configuration module 222 may comprise combinational logic that receives, as inputs, the operating parameters 230 and outputs one or more power gating settings based thereon. Alternatively, the configuration module 222 may comprise a more complicated programmable device, such a microcontroller. For the illustrated example, the configuration module 222 is arranged to configure the power gating settings by way of storing appropriate values within registers 224. The power gating module 220 of FIG. 2 further comprises a power control module 226 arranged to read the power gating settings stored in registers 224, and to apply the read power gating settings. For example, the power control module 226 may be arranged to control one or more power gating elements (not shown), for example transistors, located within power supply lines to one or more functional blocks of the signal processing module 210, and to switch the transistors ‘ON’ or ‘OFF’ based on the read power gating settings.

The power gating module 220 of FIG. 2 is further operably coupled to a clock distribution network 240 of the signal processing module 210, and arranged to configure the clock distribution network 240 for at least part of signal processing module 210 in accordance with the at least one determined power gating setting. In particular, when the power gating module 220 configures a power supply to a part of the signal processing module 210 to be gated, the clock distribution network 240 may be configured to also gate parts of the clock distribution network 240 corresponding to that part of the signal processing module 210 for which a power supply has been gated. In this manner, power need not be wasted unnecessarily in driving a clock signal. For example, the configuration module 222 may be arranged to configure clock gating settings in a similar manner as for the power gating settings, and to store such clock gating settings within register 224. The power control module 226 may then be further arranged to read the clock gating settings, and to apply the read clock gating settings to the clock distribution network 240.

For the illustrated example the signal processing module 210 and power gating module 220 are located on a single integrated circuit device 105, and the power gating module 220 is arranged to apply power gating in accordance with one or more configured power gating settings for one or more of the signal processing cores 212, 214, the memory element 216 and/or one or more other functional logic blocks 218, such functional logic blocks comprising, by way of example only, a video accelerator, graphical accelerator, serial/parallel interface, etc. However, other examples of the present invention are not limited to the specific implementation illustrated in FIG. 2, and may equally be applied using alternative implementations and to alternative system architectures. For example, power gating modules adapted in accordance with some example embodiments of the invention may be implemented within signal processing systems provided on a plurality of integrated circuit devices, or provided on one or more alternative structures (for example printed circuit boards). Furthermore, components of such power gating modules may be dispersed over the different integrated circuit devices or alternative structures. Furthermore, power gating modules adapted in accordance with some example embodiments of the invention may be implemented within signal processing systems comprising only a single signal processing core, or any other alternative architectural variation.

For the example described above, the power gating module 220 has been described as configuring power gating settings, and applying such power gating settings, such that the rate (or frequency) at which a power supply is cyclically gated may be configured to provide an optimal balance between performance and power consumption, depending on operating conditions and the like. In particular, for the above described example, the power gating module 220 has been described as configuring the power gating settings in order to configure a gating cycle such that a power supply is switched ‘ON’ (conducting) for a given period and switched ‘OFF’ (non-conducting) for a substantially equal period, such that the effective power supply duty cycle is half the cyclic period. However, in other examples, the power gating module 220 may be arranged to configure power gating settings, and to apply such power gating settings whereby the power gating module 220 configures a gating cycle such that the effective power supply duty cycle comprises other than half the cyclic period, and the power gating module 220 may be arranged to configure gating cycles comprising a range of different power supply duty cycle ratios.

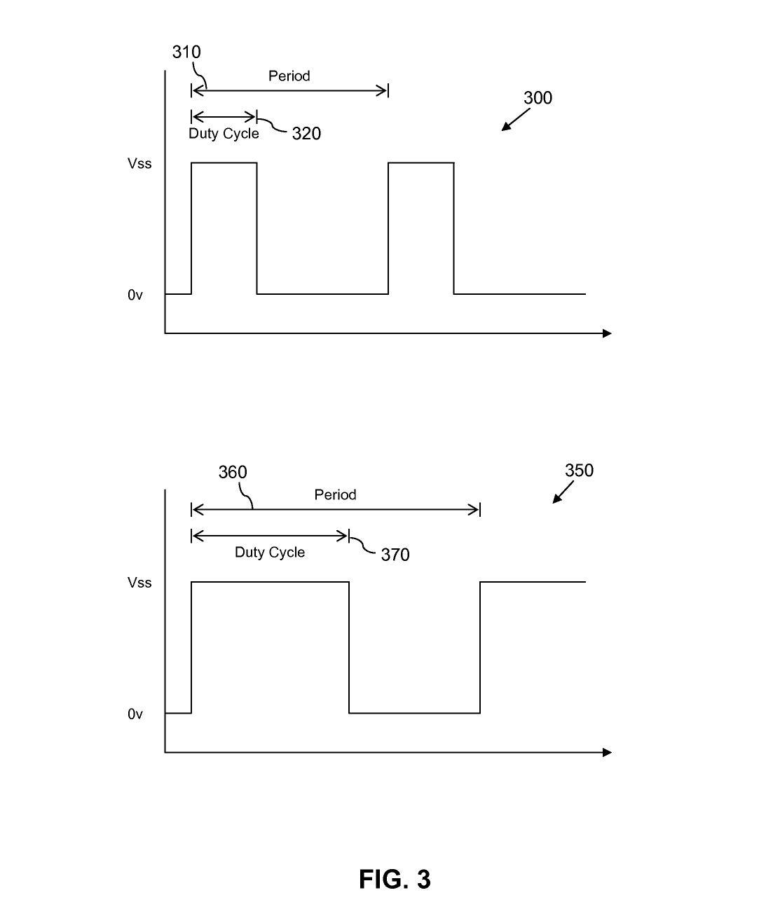

For example, FIG. 3 illustrates an example of a first gating cycle 300 as may be configured by the power gating module 220 of FIG. 2. This first gating cycle 300 comprises a first cyclic period 310, and a first power supply duty cycle 320 (e.g. that part of the gating cycle for which the power supply is switched ‘on’). For this first gating cycle 300, the first power supply duty cycle 320 is significantly less than half the first cyclic period 310. FIG. 3 also illustrates an example of a second gating cycle 350 as may be alternatively configured by the power gating module 220. As illustrated, this second gating cycle 350 comprises a second cyclic period 360 and a second power supply duty cycle 370. This second cyclic gating rate 350 comprises a longer cyclic period 360 than the first cyclic period 310 of the first gating cycle 300, and also a proportionately larger power supply duty cycle 370. Thus, the power gating module 220 is able to not only vary the cyclic frequency at which the gating is applied, but also the proportion of time within each gating cycle that the power supply may be switched ‘on’.

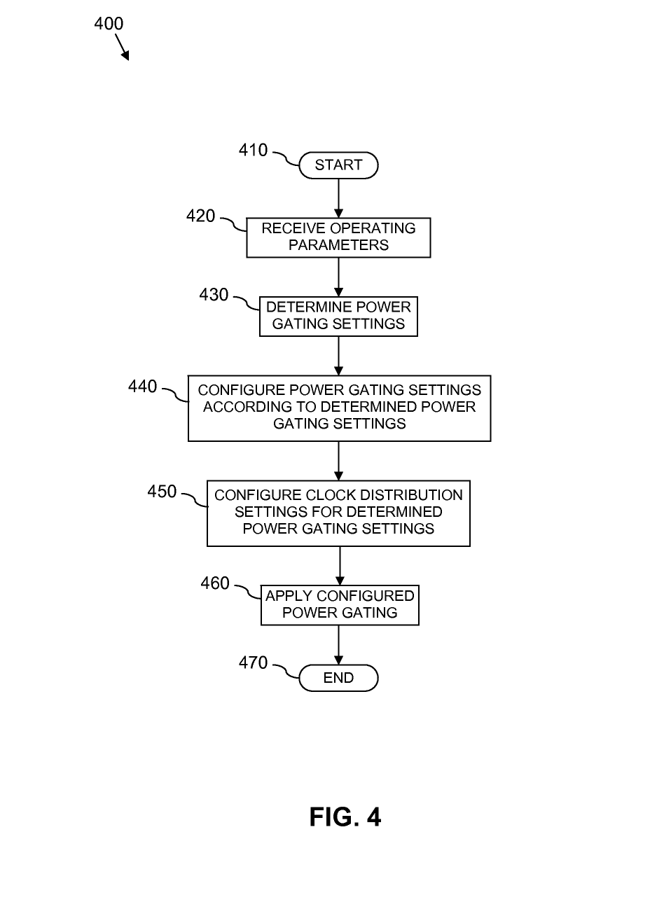

Referring now to FIG. 4, there is illustrated an example of a simplified flowchart 400 of a method for dynamically controlling a gating of at least one power supply to at least a part of a signal processing module, such as may be implemented by the power gating module 220 of FIG. 2. The method starts at 410 and moves on to step 420 where one or more operating parameters are received. For example, such operating parameters may comprise an indication of an ambient temperature, an indication of a supply voltage for at least a part of the at least one signal processing module, an indication of a processing load for at least a part of the at least one signal processing module, an indication of a configurable setting, etc. Next, at step 430, power gating settings are determined based on the received parameters, and power gating settings are then configured according to the determined power gating settings at step 440. For the illustrated example, clock distribution settings are also configured according to the determined power gating settings at step 450. The configured power gating settings are then applied at step 460, and the method ends at step 470.

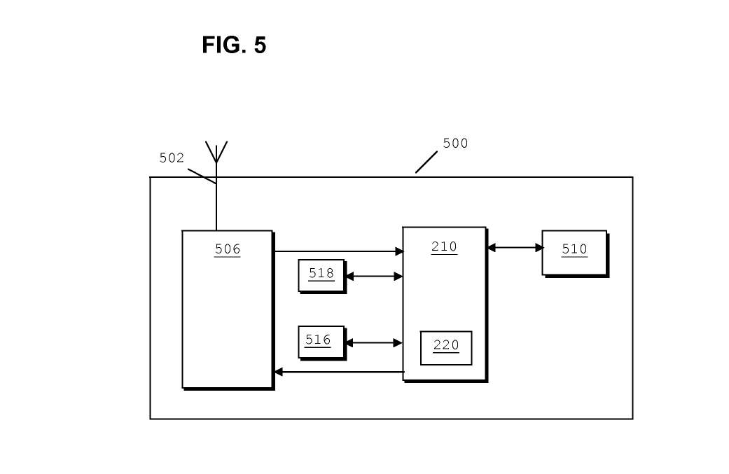

Referring to FIG. 5, there is illustrated an example of a simplified block diagram of part of an electronic device 500 that may be adapted to support the aforementioned concept. The electronic device 500, in the context of the illustrated example, is a mobile telephone handset comprising an antenna 502. As such, the electronic device 500 contains a variety of well known radio frequency components or circuits 506, operably coupled to the antenna 502 that will not be described further herein. The electronic device 500 further comprises signal processing logic, which for the illustrated example comprises the signal processing module 210 of FIG. 2. An output from the signal processing logic 508 is provided to a suitable user interface (UI) 510 comprising, for example, a display, keypad, microphone, speaker etc.

For completeness, the signal processing logic 508 is coupled to a memory element 516 that stores operating regimes, such as decoding/encoding functions and the like and may be realised in a variety of technologies, such as random access memory (RAM) (volatile), (non-volatile) read only memory (ROM), Flash memory or any combination of these or other memory technologies. A timer 518 is typically coupled to the signal processing logic 508 to control the timing of operations within the electronic device 500.

The signal processing module 210 comprises power gating control module 220 arranged to control gating of at least one power supply to at least a part of the signal processing module 210, for example to one or more of the processing cores, memory element and/or functional logic blocks. In particular for the illustrated example, the power gating control module 220 is arranged to receive one or more operating parameters, configure at least one power gating setting based at least partly on the one or more received operating parameters, and apply power gating for at least part of the signal processing module 210 in accordance with the at least one configured power gating setting.

The invention may also be implemented in a computer program for running on a computer system, at least including code portions for performing steps of a method according to the invention when run on a programmable apparatus, such as a computer system or enabling a programmable apparatus to perform functions of a device or system according to the invention.

A computer program is a list of instructions such as a particular application program and/or an operating system. The computer program may for instance include one or more of: a subroutine, a function, a procedure, an object method, an object implementation, an executable application, an applet, a servlet, a source code, an object code, a shared library/dynamic load library and/or other sequence of instructions designed for execution on a computer system.

The computer program may be stored internally on computer readable storage medium or transmitted to the computer system via a computer readable transmission medium. All or some of the computer program may be provided on computer readable media permanently, removably or remotely coupled to an information processing system. The computer readable media may include, for example and without limitation, any number of the following: magnetic storage media including disk and tape storage media; optical storage media such as compact disk media (e.g., CD-ROM, CD-R, etc.) and digital video disk storage media; non-volatile memory storage media including semiconductor-based memory units such as FLASH memory, EEPROM, EPROM, ROM; ferromagnetic digital memories; MRAM; volatile storage media including registers, buffers or caches, main memory, RAM, etc.; and data transmission media including computer networks, point-to-point telecommunication equipment, and carrier wave transmission media, just to name a few.

A computer process typically includes an executing (running) program or portion of a program, current program values and state information, and the resources used by the operating system to manage the execution of the process. An operating system (OS) is the software that manages the sharing of the resources of a computer and provides programmers with an interface used to access those resources. An operating system processes system data and user input, and responds by allocating and managing tasks and internal system resources as a service to users and programs of the system.

The computer system may for instance include at least one processing unit, associated memory and a number of input/output (I/O) devices. When executing the computer program, the computer system processes information according to the computer program and produces resultant output information via I/O devices.

In the foregoing specification, the invention has been described with reference to specific examples of embodiments of the invention. It will, however, be evident that various modifications and changes may be made therein without departing from the broader spirit and scope of the invention as set forth in the appended claims.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Although specific conductivity types or polarity of potentials have been described in the examples, it will appreciated that conductivity types and polarities of potentials may be reversed.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “de-assert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality. For example, for the example illustrated in FIG. 2, the power gating module 220 is illustrated as comprising discrete configuration a power control modules 222, 226. However it will be appreciated that the power gating module 220 may be implemented using any suitable components and distribution of functionality. Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermediary components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device, such as illustrated in FIG. 2 with respect to the integrated circuit device 205. Alternatively, the examples may be implemented as any number of separate integrated circuits or separate devices interconnected with each other in a suitable manner.

Also for example, the examples, or portions thereof, may implemented as soft or code representations of physical circuitry or of logical representations convertible into physical circuitry, such as in a hardware description language of any appropriate type.

Also, the invention is not limited to physical devices or units implemented in non-programmable hardware but can also be applied in programmable devices or units able to perform the desired device functions by operating in accordance with suitable program code, such as mainframes, minicomputers, servers, workstations, personal computers, notepads, personal digital assistants, electronic games, automotive and other embedded systems, cell phones and various other wireless devices, commonly denoted in this application as ‘computer systems’.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

1. An integrated circuit device comprising: at least one signal processing module; and
a power gating control module arranged to control gating of at least one power supply to at least a part of the at least one signal processing module
wherein the power gating control module is arranged to receive at least one operating parameter, configure at least one power gating setting of the power gating control module based at least partly on the at least one received operating parameter, and apply power gating for at least part of the at least one signal processing module in accordance with the at least one configured power gating setting.

2. The integrated circuit device of claim 1 wherein the power gating control module comprises a state-retention power gating control module arranged to control gating of at least one power supply to at least a part of the at least one signal processing module whilst a power supply to at least one state element of the at least part of the at least one signal processing module for which power is gated is maintained.

3. The integrated circuit device of claim 1, wherein the at least one operating parameter received by the power gating control module comprises at least one from a group consisting of:
an indication of an ambient temperature;
an indication of a supply voltage for at least a part of the at least one signal processing module;
an indication of a processing load for at least a part of the at least one signal processing module; and
an indication of a configurable setting.

4. The integrated circuit device of claim 3 wherein the power gating control module is arranged to receive an indication of an ambient temperature and is further arranged:
upon receipt of an indication of a low ambient temperature to configure a lower frequency power gating setting for at least part of the at least one signal processing module; or
upon receipt of an indication of a high ambient temperature to configure a higher frequency power gating setting for at least part of the at least one signal processing module.

5. The integrated circuit device of claim 1 wherein the power gating control module is further arranged to configure a clock distribution network for at least part of the at least one signal processing module in accordance with the at least one configured power gating setting.

6. The integrated circuit device of claim 1 wherein the power gating module is arranged to apply power gating in accordance with the at least one configured power gating setting for at least one from a group consisting of:
at least one signal processing core;
a memory element; and
a functional logic block.

7. A signal processing system comprising:
at least one signal processing module;
a power gating control module arranged to control gating of at least one power supply to at least a part of the at least one signal processing module,
wherein the power gating control module is arranged to receive at least one operating parameter, configure at least one power gating setting of the power gating control module based at least partly on the at least one received operating parameter, and apply power gating for at least part of the at least one signal processing module in accordance with the at least one configured power gating setting.

8. (canceled)

9. (canceled)

10. A method for dynamically controlling gating of at least one power supply to at least a part of a signal processing module, the method comprising:
receiving at least one operating parameter;
configuring at least one power gating setting of the power gating control module based at least partly on the at least one received operating parameter; and
applying power gating for at least part of the signal processing module in accordance with the at least one configured power gating setting.

11. The integrated circuit device of claim 2, wherein the at least one operating parameter received by the power gating control module comprises at least one from a group consisting of:
an indication of an ambient temperature;
an indication of a supply voltage for at least a part of the at least one signal processing module;
an indication of a processing load for at least a part of the at least one signal processing module; and
an indication of a configurable setting.

12. The integrated circuit device of claim 2 wherein the power gating control module is further arranged to configure a clock distribution network for at least part of the at least one signal processing module in accordance with the at least one configured power gating setting.

13. The integrated circuit device of claim 3 wherein the power gating control module is further arranged to configure a clock distribution network for at least part of the at least one signal processing module in accordance with the at least one configured power gating setting.

14. The integrated circuit device of claim 4 wherein the power gating control module is further arranged to configure a clock distribution network for at least part of the at least one signal processing module in accordance with the at least one configured power gating setting.

15. The integrated circuit device of claim 2 wherein the power gating module is arranged to apply power gating in accordance with the at least one configured power gating setting for at least one from a group consisting of:
at least one signal processing core;
a memory element; and
a functional logic block.

16. The integrated circuit device of claim 3 wherein the power gating module is arranged to apply power gating in accordance with the at least one configured power gating setting for at least one from a group consisting of:
at least one signal processing core;
a memory element; and
a functional logic block.

17. The integrated circuit device of claim 4 wherein the power gating module is arranged to apply power gating in accordance with the at least one configured power gating setting for at least one from a group consisting of:
at least one signal processing core;
a memory element; and
a functional logic block.

18. The integrated circuit device of claim 5 wherein the power gating module is arranged to apply power gating in accordance with the at least one configured power gating setting for at least one from a group consisting of:
at least one signal processing core;
a memory element; and
a functional logic block.
